(19) United States
(12) Patent Application Publication
(10) Pub. No.: US 2018/0151732 A1
(43) Pub. Date: May 31, 2018

(54) RESISTANCE REDUCTION IN TRANSISTORS HAVING EPITAXIALLY GROWN SOURCE/DRAIN REGIONS

(71) Applicant: INTEL CORPORATION, Santa Clara, CA (US)

(72) Inventors: RISHABH MEHANDRU, Beaverton, OR (US); ANAND S. MURTHY, Portland, OR (US); TAHIR GHANI, Portland, OR (US); GLENN A. GLASS, Portland, OR (US); KARTHIK JAMBUNATHAN, Hillsboro, OR (US); SEAN T. MA, Portland, OR (US); CORY E. WEBER, Hillsboro, OR (US)

(73) Assignee: INTEL CORPORATION, Santa Clara, CA (US)

(21) Appl. No.: 15/575,008

(22) PCT Filed: Jun. 19, 2015
(86) PCT No.: PCT/US2015/036688

§ 371 Date: Nov. 17, 2017

(51) Int. Cl. H01L 29/78; H01L 29/167; H01L 29/08; H01L 29/165; H01L 29/66; H01L 21/306; H01L 21/02; H01L 29/06; H01L 21/762

(52) U.S. Cl. CPC H01L 29/7848; H01L 29/167; H01L 29/0847; H01L 29/165; H01L 29/66795; H01L 21/30604; H01L 27/0924; H01L 21/02532; H01L 21/02579; H01L 29/7851; H01L 21/0245; H01L 29/0649; H01L 21/76224; H01L 29/66636

(57) ABSTRACT

Techniques are disclosed for resistance reduction in p-MOS transistors having epitaxially grown boron-doped silicon germanium (SiGe:B) S/D regions. The techniques can include growing one or more interface layers between a silicon (Si) channel region of the transistor and the SiGe:B replacement S/D regions. The one or more interface layers may include: a single layer of boron-doped Si (Si:B); a single layer of SiGe:B, where the Ge content in the interface layer is less than that in the resulting SiGe:B S/D regions; a graded layer of SiGe:B, where the Ge content in the alloy starts at a low percentage (or 0%) and is increased to a higher percentage; or multiple stepped layers of SiGe:B, where the Ge content in the alloy starts at a low percentage (or 0%) and is increased to a higher percentage at each step. Inclusion of the interface layer(s) reduces resistance for on-state current flow.

### BACKGROUND

Increased performance and yield of circuit devices on a substrate, including transistors, diodes, resistors, capacitors, and other passive and active electronic devices formed on a semiconductor substrate, are typically major factors considered during design, manufacture, and operation of those devices. For example, during design and manufacture or forming of metal-oxide-semiconductor (MOS) transistor semiconductor devices, such as those used in complementary metal-oxide-semiconductor (CMOS) devices, it is often desired to increase movement of electrons (carriers) in n-type MOS device (n-MOS) channels and to increase movement of positive charged holes (carriers) in p-type MOS device (p-MOS) channels. Typical CMOS transistor devices utilize silicon as the channel material for both hole and electron majority carrier MOS channels. Example devices employ transistors in planar, fin-FET, and nanowire geometries, among others.

### BRIEF DESCRIPTION OF THE DRAWINGS

FIG. 1 illustrates a method of forming an integrated circuit, in accordance with various embodiments of the present disclosure.

FIGS. 2A-H illustrate example structures that are formed when carrying out the method of FIG. 1, in accordance with various embodiments of the present disclosure.

FIG. 2I shows a cross-sectional view about the plane A-A in FIG. 2H, in accordance with an embodiment of the present disclosure.

FIG. 3 shows a cross-sectional view about the plane A-A in FIG. 2H to illustrate multiple interface layers and/or a graded interface layer, in accordance with an embodiment of the present disclosure.

FIG. 4A illustrates an example integrated circuit including two transistor structures having finned configurations, in accordance with an embodiment of the present disclosure.

FIG. 4B illustrates an example integrated circuit including two transistor structures having nanowire configurations, in accordance with an embodiment of the present disclosure.

FIG. 4C illustrates an example integrated circuit including two transistor structures, one having a finned configuration and one having a nanowire configuration, in accordance with an embodiment of the present disclosure.

FIG. 5A illustrates a band diagram schematic of a conventional p-MOS transistor device.

FIG. 5B illustrates a band diagram schematic of a p-MOS transistor device formed in accordance with an embodiment of the present disclosure.

FIG. 6 illustrates a computing system implemented with integrated circuit structures or transistor devices formed using the techniques disclosed herein, in accordance with various embodiments of the present disclosure.

### DETAILED DESCRIPTION

Techniques are disclosed for resistance reduction in p-MOS transistors having epitaxially grown boron-doped silicon germanium (SiGe:B) S/D regions. The techniques can include growing one or more interface layers between a silicon (Si) channel region of the transistor and the SiGe:B replacement S/D regions. The one or more interface layers may include: a single layer of boron-doped Si (Si:B); a single layer of SiGe:B, where the Ge content in the interface layer is less than that in the resulting SiGe:B S/D regions; a graded layer of SiGe:B, where the Ge content in the alloy starts at a low percentage (or 0%) and is increased to a higher percentage; or multiple stepped layers of SiGe:B, where the Ge content in the alloy starts at a low percentage (or 0%) and is increased to a higher percentage at each step. In some cases, where the boron-doped interface layers are exposed to heat treatment during one or more annealing processes, the boron may spread out to surrounding layers. Accordingly, the boron-doped interface layers may occupy a narrower or wider region than originally deposited, depending on the thermal history used to complete formation of the semiconductor device(s). The techniques improve the valance-band offset between the Si channel and SiGe:B S/D regions by inclusion of the interface layer(s), thereby providing an improved interface region for carriers to tunnel through during on-state current. For example, the interface layers can improve performance by achieving increases of at least 10-50% in drive current. Numerous variations and configurations will be apparent in light of this disclosure.

General Overview

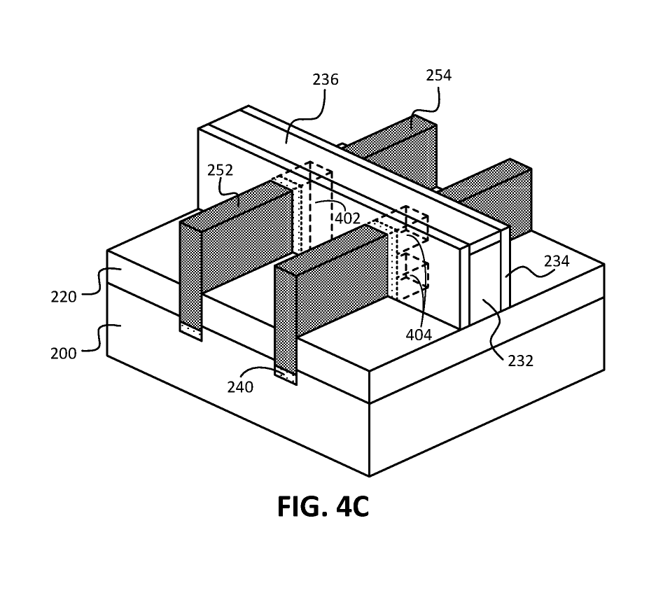

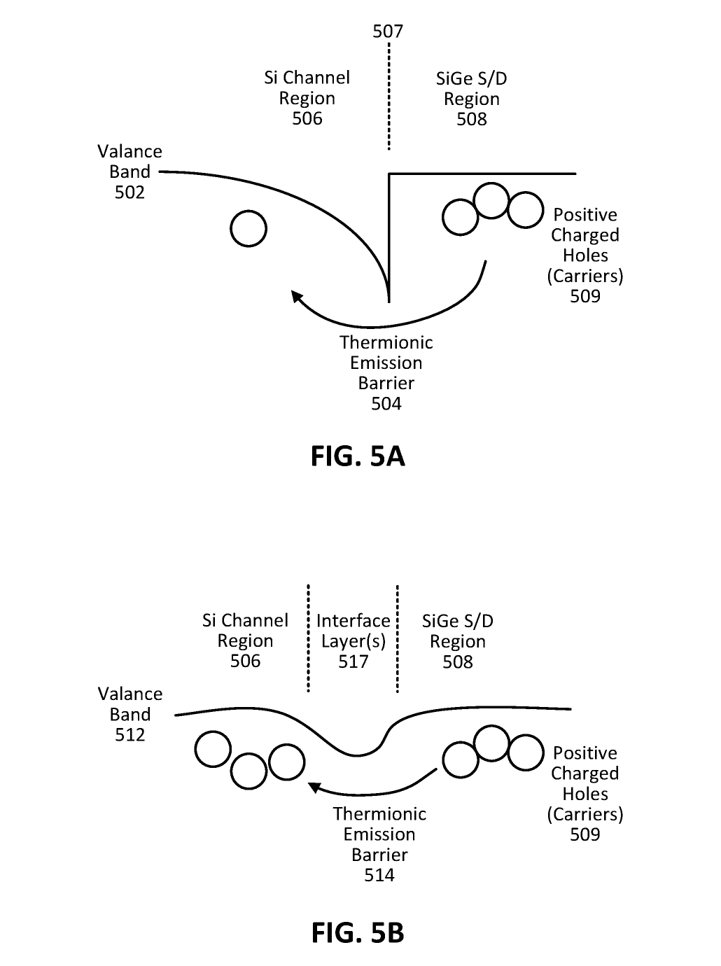

When forming a transistor, epitaxially grown boron-doped silicon germanium (SiGe:B) source/drain (S/D) regions can provide high stress for p-MOS silicon (Si) devices to enhance mobility in the channel region. However, such a replacement of the S/D regions can form a hetero interface that results in a valance-band discontinuity between the Si channel and SiGe S/D regions. The valance-band offset can cause a large degradation in on-state current. For example, FIG. 5A illustrates a band diagram schematic of a conventional p-MOS transistor device. As can be seen, valance band 502 is shown for a Si channel region 506 and a SiGe S/D region 508. A valance band offset arises at the Si/SiGe hetero interface due to band-structure differences between the two materials. This results in a large drop in on-state current due to increased resistance as a result of positive charged holes (carriers) 509 needing to go over the thermionic emission barrier 504 shown. The reduction in on-state current is undesirable as it leads to a decrease in performance. One technique to address this issue utilizes boron out-diffusion from thermal cycles post SiGe:B deposition to provide sufficient doping across the hetero-interface barrier. However, such a technique results in a large diffusion tail going into the channel, which negatively impacts short channel effects, thereby degrading overall device performance.

Thus, and in accordance with one or more embodiments of the present disclosure, techniques are disclosed for resistance reduction in p-MOS transistors having epitaxially grown SiGe S/D regions. In some embodiments, the techniques include growing one or more interface layers between the Si channel region and the SiGe:B replacement S/D regions. In some such embodiments, the one or more interface layers may include: a single layer of boron-doped Si (Si:B); a single layer of SiGe:B, where the Ge content in the interface layer is less than that in the resulting SiGe:B S/D regions; a graded layer of SiGe:B, where the Ge content in the alloy starts at a low percentage (or 0%) and is increased to a higher percentage; and/or multiple stepped layers of SiGe:B, where the Ge content in the alloy starts at a low percentage (or 0%) and is increased to a higher percentage. For ease of description, SiGe may be referred to herein as Si₁₋ₓGeₓ where x represents the percentage of Ge in the SiGe alloy (in decimal format) and 1-x represents the percentage of Si in the SiGe alloy (in decimal format). For example, if x is 0.3, then the SiGe alloy comprises 30% Ge and 70% Si, or if x is 0, then the SiGe alloy comprises 0% Ge and 100% Si, or if x is 0.6, then the SiGe alloy comprises 60% Ge and 50% Si, or if x is 1, then the SiGe alloy comprises 100% Ge and 0% Si. Accordingly, Si may be referred to herein as SiGe (Si₁₋ₓGeₓ where x is 0) and Ge may be referred to herein as SiGe (Si₁₋ₓGeₓ where x is 1).

As previously described, in some embodiments, the interface layer(s) between the Si channel region and the SiGe:B replacement S/D regions may comprise a single layer of Si:B. In some such embodiments, the single Si:B interface layer may have a thickness of 1-10 nm, and more specifically a thickness of 2-5 nm, or some other suitable thickness depending on the end use or target application. In some embodiments, the interface layer(s) may comprise a single layer of boron-doped silicon germanium (SiGe:B). In some such embodiments, the single Si:B interface layer may have a thickness of 1-10 nm, and more specifically a thickness of 2-5 nm, or some other suitable thickness depending on the end use or target application. Further, in some such embodiments, the percentage of Ge content in the single interface layer may be less than that in the resulting SiGe:B S/D regions. For example, if the resulting SiGe:B S/D regions comprises 30% Ge, then the interface layer may be deposited with 15% Ge. Accordingly, in some embodiments, the percentage of Ge content in the SiGe:B S/D regions may determine the percentage of Ge content used in the interface layer(s), as will be apparent in light of the present disclosure. For example, the percentage of Ge content in the interface layer(s) may be selected to be 10-25% lower than the percentage of Ge content in the SiGe:B S/D regions. As used herein, note that “single layer” refers to a continuous layer of the same material and may have an arbitrary thickness ranging from a monolayer to a relatively thick layer in the nanometer range (or thicker, if so desired). Further note that such a single layer may be deposited, for example, in multiple passes or epitaxial growing cycles so as to actually comprise a plurality of sub-layers of common material that make up the overall single layer of that common material. Further note that one or more components of that single layer may be graded from a first concentration to a second concentration during the deposition process.

As used herein, note that “single layer” refers to a continuous layer of the same material and may have an arbitrary thickness ranging from a monolayer to a relatively thick layer in the nanometer range (or thicker, if so desired). Also note that such a single layer may be deposited, for example, so as to actually comprise a plurality of sub-layers of common material that make up the overall single layer of that common material. Further note that one or more components of that single layer may be graded from a first concentration to a second concentration during the deposition process.

In some embodiments, the interface layer(s) may include multiple SiGe:B layers, where the percentage of Ge content in the interface layers is increased in a step-wise manner. For example, in such an embodiment, there may be three interface layers between the Si channel region and each of the SiGe:B S/D regions, where the layer nearest the channel region has a first percentage of Ge content, the middle layer has a second percentage of Ge content greater than the first percentage, and the layer nearest the corresponding S/D region has a third percentage of Ge content greater than the second percentage (but less than the percentage of Ge content in the SiGe:B S/D regions. In such an example, the first percentage may comprise 0% Ge content (i.e., Si:B), the second percentage may comprise 10% Ge content, and the third percentage may comprise 20% Ge content, just to name a specific example. In such a specific example, the Ge content in the SiGe:B S/D regions may comprise 30% Ge content. In some embodiments, the interface layer(s) may include a graded layer, where the percentage of Ge content in the graded layer increases during deposition. In other words, the percentage of Ge content would increase from a low percentage or 0% near the channel region to a higher percentage near the corresponding S/D region. In some such embodiments, the graded layer may have a thickness of 2-10 nm, or some other suitable thickness depending on the end use or target application.

Numerous benefits can be achieved by the inclusion of one or more interface layers (as variously described herein) between the Si channel region and SiGe:B S/D regions of a p-MOS transistor. For example, one benefit can be seen through the differences in the example valance bands of FIGS. 5A and 5B. The valance band 502 of the conventional device in FIG. 5A shows a valance band offset that arises at the hetero-interface 507 between the Si channel region 506 and the SiGe S/D region 508 due to band-structure differences between the two materials. Such a hetero-interface 507 causes increased resistance during on-state current, thereby decreasing on-state current performance, because positive charged holes (carriers) 509 are required to go over a thermionic emission barrier 504 having high resistance. The p-MOS transistor device of FIG. 5B formed using the techniques variously described herein has a lower thermionic emission barrier 514 as compared to the device of FIG. 5A, as a result of the improved valance band 512 formed by the inclusion of interface layer(s) 517. This improved valance band 512 results in decreased resistance during on-state current, thereby increasing on-state current performance. In an example embodiment where the interface layer(s) 517 comprise a single layer of Si:B, there will be enough p-type dopant across the hetero-interface to allow carriers 509 to tunnel through the interface, rather than relying on traveling over the large hetero-interface 507 thermionic emission barrier 504 of the conventional device of FIG. 5A. In an example embodiment where the interface layer(s) 517 comprise a graded layer of SiGe:B or stepped layers of SiGe:B (where the Ge content is increased in a graded or stepped manner, respectively), the carriers 509 can flow freely or in an improved manner from the SiGe S/D regions 508 to the Si channel region 506. Such performance gains have been measured in the linear regime with a gate bias of 0.6V and a bias of 0.05V on the drain to produce increases of 10-50% in drive current, depending upon the interface layer(s) used; however, higher increases may be achievable depending upon the particular configuration used.

Upon analysis (e.g., using scanning/transmission electron microscopy (SEM/TEM), composition mapping, and/or atom probe imaging/3D tomography), a structure or device configured in accordance with one or more embodiments will effectively show one or more interface layers as variously described herein. For example, in embodiments where the interface layer(s) comprise a single Si:B layer, the SiGe S/D region could be etched out and the boron doping in the silicon in the interface layer could be measured using analytic techniques to determine if there is a sharp box-like boron doping profile outside of the SiGe S/D regions. Further, in embodiments where the interface layer(s) comprise stepped multi-layers or a graded layer of increasing percentages of Ge content, the low concentration of Ge or the graded Ge content could be detected by doing an elemental map in TEM or by collecting atom probe images which would show the 3D profile of germanium atoms. Detection of the interface layer(s) may also be achieved by measuring whether there is a diffusion tail in the Si channel region and the size of that tail. This is because conventional p-MOS transistor devices that include epitaxially grown SiGe:B S/D regions may utilize boron out-diffusion from thermal cycles post SiGe:B deposition to provide sufficient doping across the hetero-interface barrier existing between the Si channel region and the SiGe:B S/D regions. However, such a conventional process results in a large diffusion tail going into the Si channel region, which causes negative short channel effects (as indicated by low threshold voltage and high source to drain current leakage), thereby degrading overall device performance. A p-MOS transistor device formed with one or more interface layers using the techniques variously described herein can be formed while keeping thermal cycle post deposition of the SiGe:B S/D regions to a minimum, thereby improving short channel effects (or at least not hurting the short channel effects), while still achieving improved on-state current. Accordingly, the techniques described herein can enable continued transistor performance at very small gate lengths by improving on-current flow bottleneck. Numerous configurations and variations will be apparent in light of this disclosure.

Architecture and Methodology

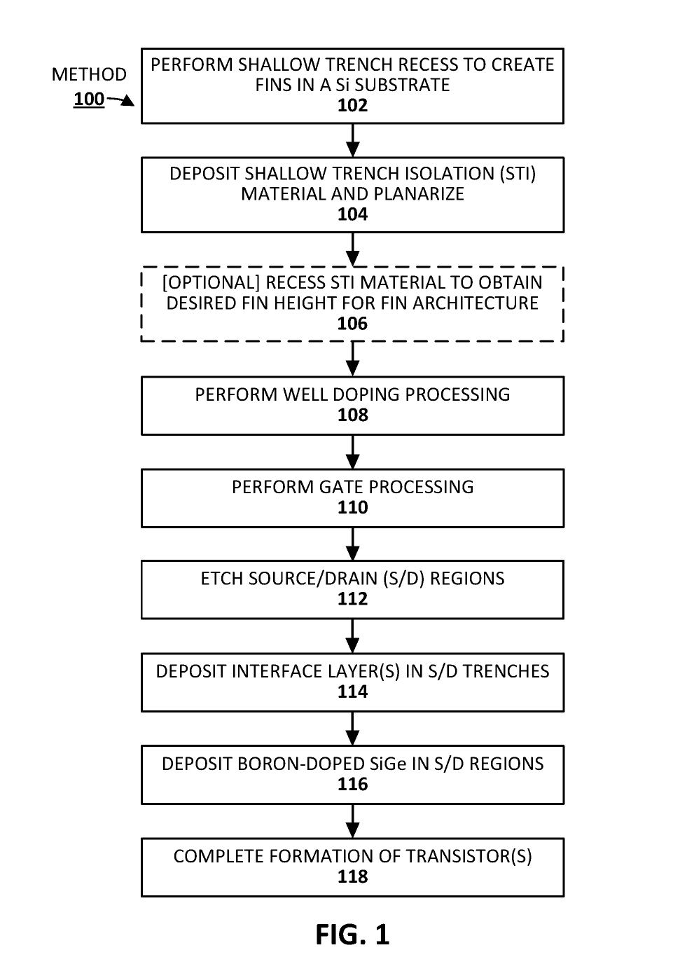

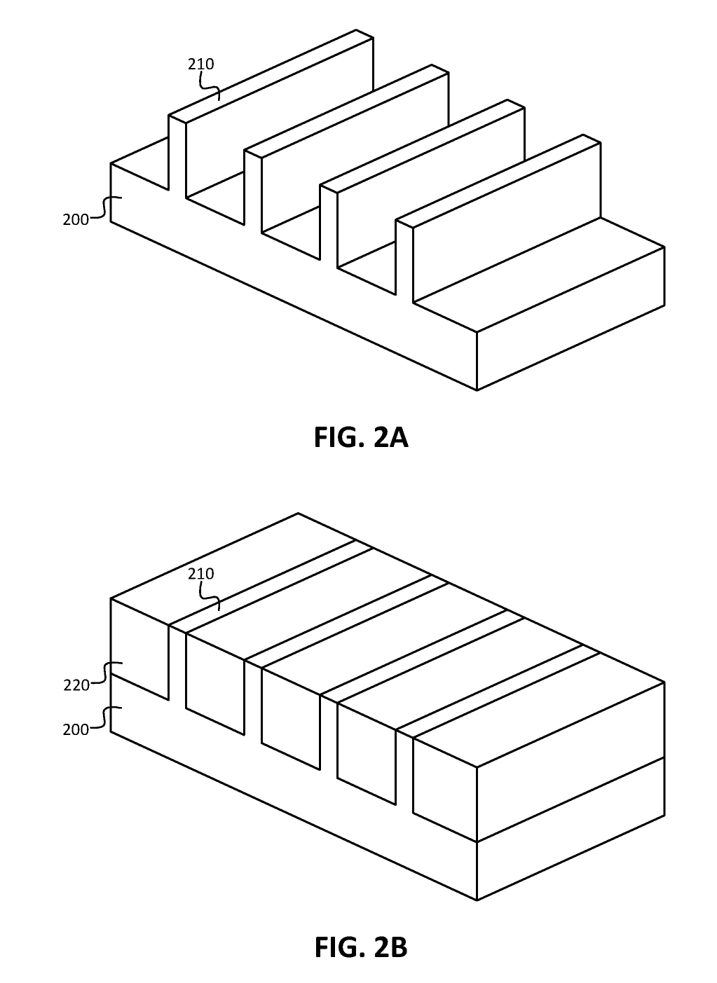

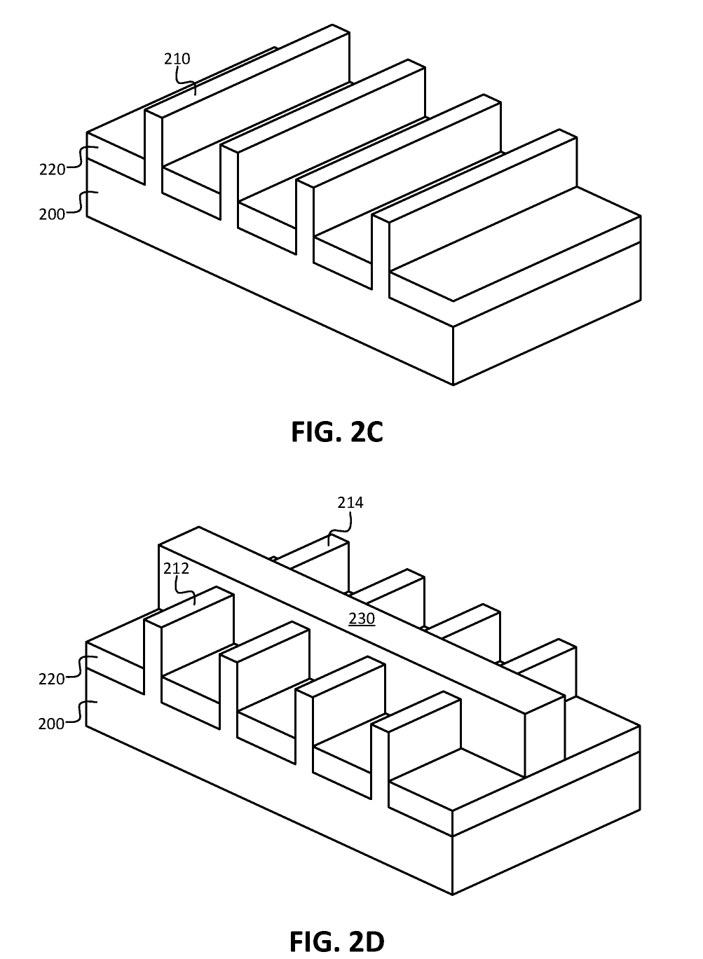

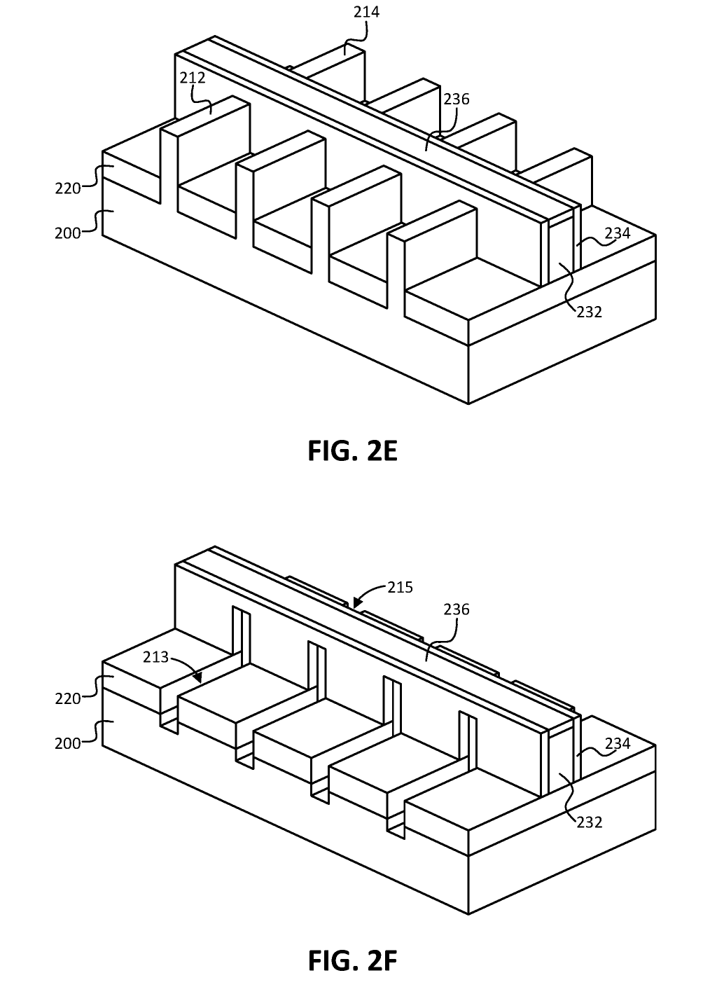

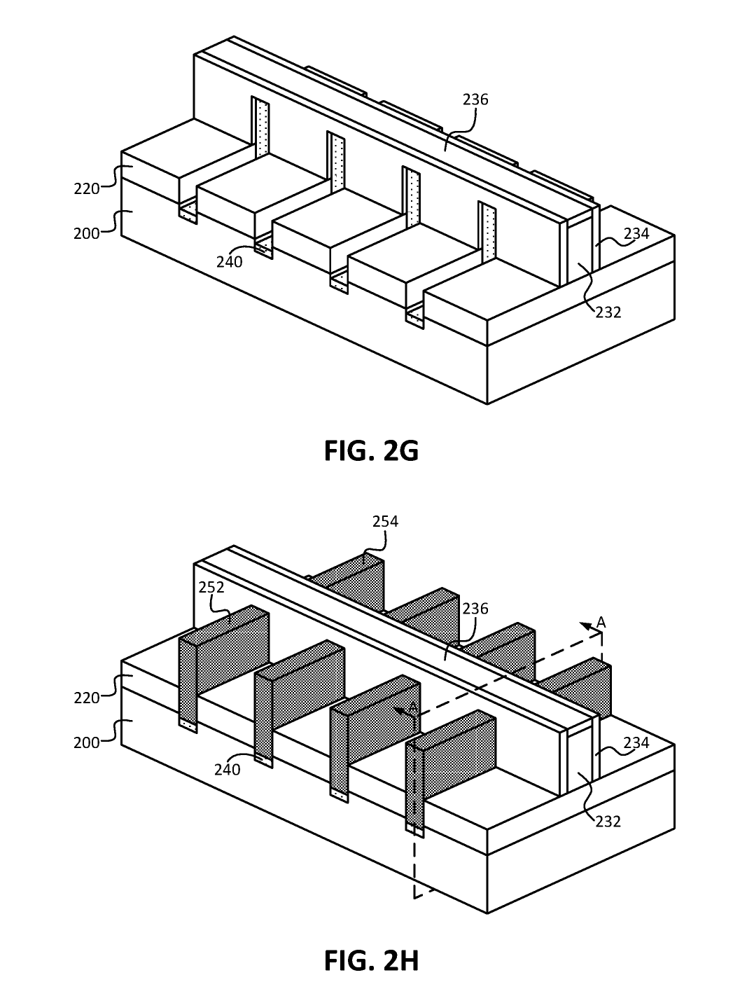

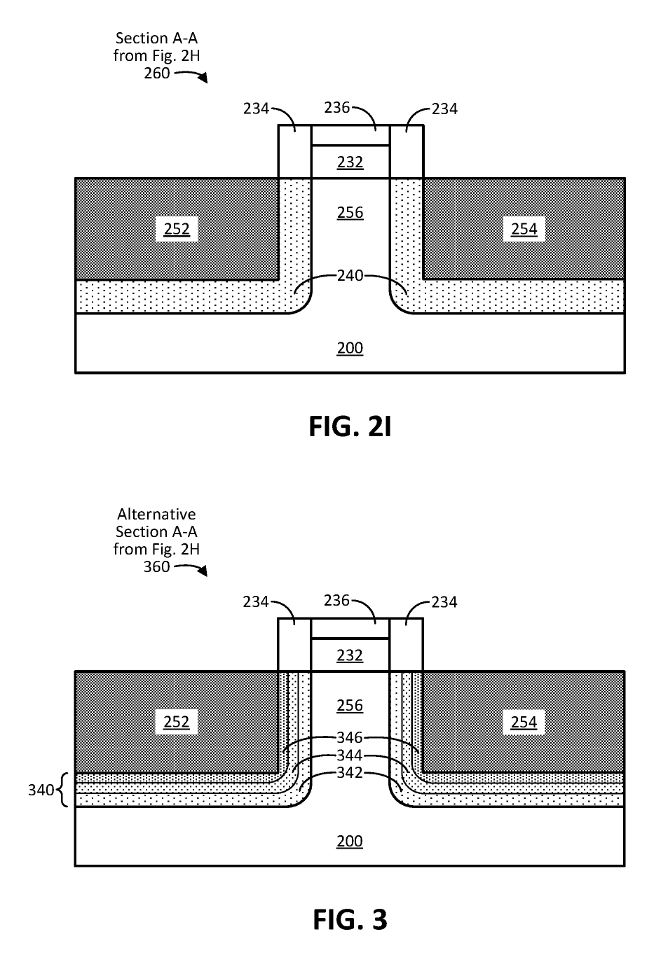

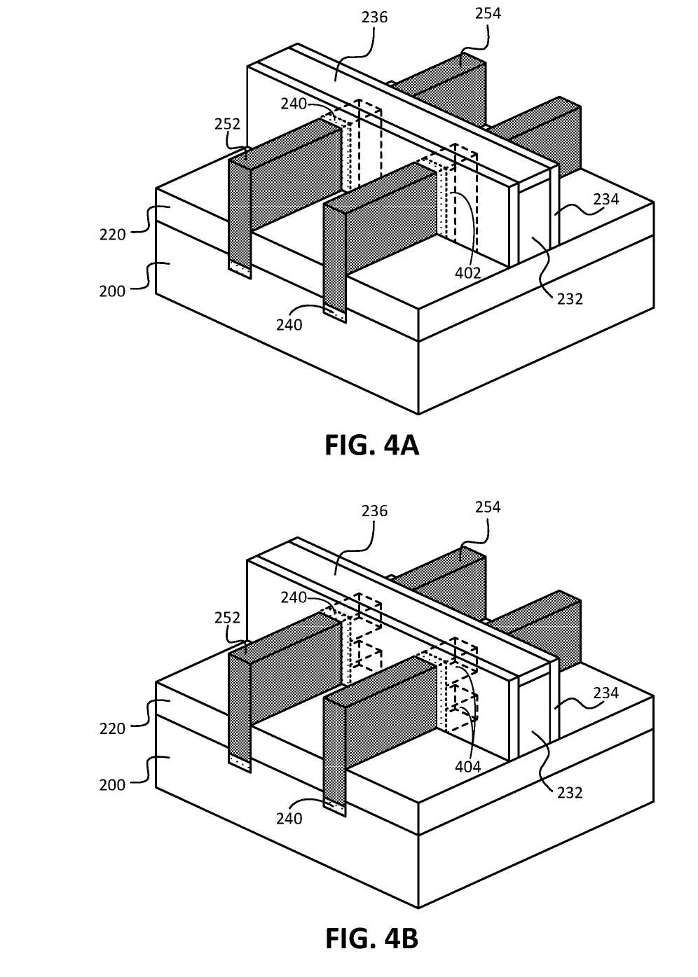

FIG. 1 illustrates a method 100 of forming an integrated circuit, in accordance with one or more embodiments of the present disclosure. FIGS. 2A-I illustrate example structures that are formed when carrying out method 100 of FIG. 1, in accordance with various embodiments. As will be apparent in light of the structures formed, method 100 discloses techniques for forming a transistor having a Si channel region, epitaxially grown SiGe:B S/D regions, and one or more interface layers therebetween. FIG. 3 illustrates an example structure similar to the structure of FIG. 2I, including multiple interface layers and/or a graded interface layer, in accordance with an embodiment. The structures of FIGS. 2A-I are primarily depicted and described herein in the context of forming finned transistor configurations (e.g., tri-gate or finFET), for ease of illustration. However, the techniques can be used to form planar, dual-gate, finned, and/or nanowire (or gate-all-around or nanoribbon) transistor configurations, or other suitable configurations, as will be apparent in light of this disclosure. For example, FIGS. 4A-C illustrate example resulting transistors, some of which include nanowire configurations, as will be discussed in more detail below.

As can be seen in FIG. 1, method 100 includes performing 102 shallow trench recess to create fins 210 in a Si substrate 200, thereby forming the example resulting structure shown in FIG. 2A, in accordance with an embodiment. In some embodiments, substrate 200 may be: a bulk substrate comprising Si; a Si on insulator (SOI) structure where the insulator material is an oxide material or dielectric material or some other electrically insulating material; or some other suitable multilayer structure where the top layer comprises Si. Fins 210 can be formed 102 from substrate 200 using any suitable etch techniques, such as one or more of the following processes: wet etching, dry etching, lithography, masking, patterning, exposing, developing, resist spinning, ashing, or any other suitable processes. In some instances, shallow trench recess 102 may be performed in-situ/without air break, while in other instances, the process 102 may be performed ex-situ.

Fins 210 (and the trenches therebetween) may be formed to have any desired dimensions, depending upon the end use or target application. Although four fins are shown in the example structure of FIG. 2A, any number of fins can be formed as desired, such as one fin, two fins, twenty fins, one hundred fins, one thousand fins, one million fins, etc. In some cases, all of the fins 210 (and the trenches therebetween) may be formed to have similar or exact dimensions (e.g., as shown in FIG. 2A), while in other cases, some of the fins 210 (and/or trenches therebetween) may be formed to have different dimensions, depending upon the end use or target application. In some embodiments, shallow trench recess 102 may be performed to create fins having height to width ratios of 3 or more and such fins may be used for non-planar transistor configurations, for example. In some embodiments, shallow trench recess 102 may be performed to create fins having height to width ratios of 3 or less and such fins may be used for planar transistor configurations, for example. Various different fin geometry will be apparent in light of the present disclosure.

Method 100 of FIG. 1 continues with depositing 104 shallow trench isolation (STI) material 220 and planarizing the structure to form the example resulting structure shown in FIG. 2B, in accordance with an embodiment. Deposition 104 of STI material 220 can be performed using any suitable techniques, such as chemical vapor deposition (CVD), plasma enhanced CVD (PECVD), atomic layer deposition (ALD), spin-on processing, and/or any other suitable process. In some instances, the surface of substrate 200 and fins 210 to be deposited on may be treated (e.g., chemical treatment, thermal treatment, etc.) prior to deposition of the STI material 220. STI material 220 may comprise any suitable insulating material, such as one or more dielectric or oxide materials (e.g., silicon dioxide).

Method 100 of FIG. 1 continues with optionally recessing 106 the STI material 220 to obtain a desired fin height for the resulting fin architecture, thereby forming the example resulting structure shown in FIG. 2C, in accordance with an embodiment. Recess 106 of STI material 220 may be performed using any suitable technique, such as one or more wet and/or dry etching processes, or any other suitable processes. In some instances, recess 106 may be performed in-situ/without air break, while in other instances, the recess 106 may be performed ex-situ. In some embodiments, recess 106 may be skipped, such as in the case where the resulting desired transistor architecture is planar, for example. Accordingly, recess 106 is optional. In some embodiments, recess 106 may be performed when the resulting desired transistor architecture is non-planar (e.g., finned or nanowire/nanoribbon architecture). Method 100 of FIG. 1 continues with performing 108 well doping processing, in accordance with an embodiment. Well doping 108 may be performed using any standard techniques, depending on the end use or target application. For example, in the case of forming p-MOS transistors, an n-type dopant may be used to dope at least the portion of the Si fin 210 to be later used as a p-MOS channel region. Example n-type dopants can include phosphorous (P) and arsenic (As), just to name a few examples. Note that well doping 108 may be performed earlier in method 100, depending upon the techniques used.

Method 100 of FIG. 1 continues with performing 110 gate 230 processing to form the example resulting structure shown in FIG. 2D, in accordance with an embodiment. Gate stack 230 may be formed using any standard techniques. For example, gate stack 230 may include gate electrode 232 shown in FIG. 2E and a gate dielectric (not show for ease of illustration) formed directly under gate electrode 232. The gate dielectric and gate electrode 232 may be formed using any suitable technique and the layers may be formed from any suitable materials. The gate dielectric can be, for example, any suitable oxide such as SiO₂ or high-k gate dielectric materials. Examples of high-k gate dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used. In general, the thickness of the gate dielectric should be sufficient to electrically isolate the gate electrode from the source and drain contacts. Further, the gate electrode 232 may comprise a wide range of materials, such as polysilicon, silicon nitride, silicon carbide, or various suitable metals or metal alloys, such as aluminum (Al), tungsten (W), titanium (Ti), tantalum (Ta), copper (Cu), titanium nitride (TiN), or tantalum nitride (TaN), for example.

In some embodiments, the gate stack 230 may be formed during a replacement metal gate (RMG) process, and such a process may include any suitable deposition technique (e.g., CVD, PVD, etc.). Such a process may include dummy gate oxide deposition, dummy gate electrode (e.g., poly-Si) deposition, and patterning hardmask deposition. Additional processing may include patterning the dummy gates and depositing/etching spacer 234 material. Additional processing may also include tip doping, depending on the end use or target application. Following such processes, the method may continue with insulator deposition, planarization, and then dummy gate electrode and gate oxide removal to expose the channel region of the transistors. Following opening the channel region, the dummy gate oxide and electrode may be replaced with, for example, a hi-k dielectric and a replacement metal gate, respectively. As can be seen in the example structure of FIG. 2E, spacers 234 were formed using standard techniques. Spacers 234 may be formed to, for example, protect the gate stack (such as gate electrode 232 and/or gate dielectric) during subsequent processing. Further note that the example structure of FIG. 2E includes hardmask 236 formed using standard techniques. Hardmask 236 may be formed to, for example, protect the gate stack (such as gate electrode 232 and/or gate dielectric) during subsequent processing.

The gate stack defines channel regions as well as source and drain regions of subsequently formed transistors, where the channel region is underneath the gate stack and the source/drain (S/D) regions are located on either side of the channel region. For example, the portion of fins 210 underneath gate stack 230 in FIG. 2D can be used for transistor channel regions and the portion of fins 212 and 214 on either side of gate stack 230 can be used for transistor S/D regions. Note that 212 could be used either for the source region or the drain region, and 214 can be used for the other region, based on the resulting configuration. Accordingly, once the gate stack is fabricated, the S/D regions 212 and 214 can be processed.

Method 100 of FIG. 1 continues with etching 112 S/D regions 212 and 214 to form the resulting example structure of FIG. 2F, in accordance with an embodiment. As can be seen in the example structure of FIG. 2F, the S/D regions 212 and 214 were lithographically patterned and etched to form trenches 213 and 215, respectively. Etch 112 can be performed using any suitable techniques, such as one or more wet and/or dry etching processes, or any other suitable processes. In some instances, etch 112 may be performed in-situ/without air break, while in other instances, the etch 112 may be performed ex-situ. Note that in this example embodiment, fin regions 212 and 214 were etched to form trenches 213 and 215. However, in structures formed for planar transistor configurations (e.g., where recess 106 is not performed), the source/drain region diffusion areas may instead be etched 112 and removed to form trenches.

Method 100 of FIG. 1 continues with depositing 114 one or more interface layers 240 in the S/D trenches 213 and 215 to form the resulting example structure of FIG. 2G, in accordance with an embodiment. Method 100 of FIG. 1 continues with depositing 116 boron-doped silicon germanium (SiGe:B) 252 and 254 on interface layer(s) 240 in the S/D regions to form the resulting example structure of FIG. 2H, in accordance with an embodiment. FIG. 2I shows a cross-sectional view 260 about the plane A-A in FIG. 2H to illustrate a single interface layer 240, in accordance with an embodiment. FIG. 3 shows a cross-sectional view 360 about the plane A-A in FIG. 2H to illustrate multiple interface layers and/or a graded interface layer 340, in accordance with an embodiment. As can be understood, layer(s) 240 is referred to as interface layer(s), because the one or more layers 240 are located at the interface of the Si channel region 256 and the SiGe:B S/D regions 252 and 254 (e.g., as can be seen in FIG. 2I). Depositions 114 and 116 may include any deposition process described herein (e.g., CVD, RTCVD, ALD, etc.), or any other suitable deposition or growth processes, depending upon the end use or target application. As will be discussed in more detail below, deposition 114 may include depositing a single interface layer, multiple interface layers, and/or a graded interface layer (where one or more materials being deposited are increased or decreased during the deposition process). In some cases, a graded layer and multiple stepped layers may be visually similar. However, in some cases, adjustments made through a graded layer may be more gradual than in stepped layers, for example.

In some embodiments, interface layer(s) may include a single layer of boron-doped silicon (Si:B). For example, interface layer 240 in FIGS. 2G-I may comprise a single layer of Si:B. In some such embodiments, the single Si:B interface layer may have a thickness of 1-10 nm, and more specifically a thickness of 2-5 nm, or some other suitable thickness depending on the end use or target application. The amount of boron doping in the Si:B interface layer can be selected as desired based on the end result or target application, such as a doping level of approximately 1.0E20 or some other suitable amount. Note that the Si:B interface layer may include a higher, lower, or equal amount of boron doping as compared to the amount of doping in the SiGe:B S/D regions. A specific example of conditions used to fabricate such a single Si:B interface layer includes a selective deposition process using dichlorosilane and/or silane, diborane, hydrochloric acid, and hydrogen carrier gas in a CVD reactor at a pressure of 20 Torr and a temperature of 700-750 degrees Celsius for example resulting in a layer with a boron concentration at or near 2E20 atoms/cm³.

In some embodiments, the interface layer(s) may include a single layer of boron-doped silicon germanium (SiGe:B). For example, interface layer 240 in FIGS. 2G-I may comprise a single layer of SiGe:B. In some such embodiments, the single SiGe:B interface layer may have a thickness of 1-10 nm, and more specifically a thickness of 2-5 nm, or some other suitable thickness depending on the end use or target application. Further, in some such embodiments, the Ge content in the interface layer may be less than that in the resulting SiGe:B S/D regions (e.g., S/D regions 252 and 254 in FIGS. 2H-I). In an example embodiment, the Ge content in the interface layer may be 5-30% lower than the Ge content in the S/D regions, such as 15-20% lower. For example, if the resulting SiGe:B S/D regions comprise 30% Ge (Si₁₋ₓGeₓ:B where x is 0.3), then the SiGe:B interface layer may comprise 15% Ge (Si₁₋ₓGeₓ:B where x is 0.15). The amount of boron doping in the SiGe:B interface layer can be selected as desired based on the end result or target application. Note that the SiGe:B interface layer may include a higher, lower, or equal amount of boron doping as compared to the amount of doping in the SiGe:B S/D regions. A specific example of conditions used to fabricate such a single SiGe:B interface layer includes a selective deposition process using dichlorosilane and/or silane, germane, diborane, hydrochloric acid, and hydrogen carrier gas in a CVD reactor at a pressure of 20 Torr and a temperature of 700 degrees Celsius for example resulting in a layer with a boron concentration at or near 2E20 atom s/cm³.

In some embodiments, interface layer(s) 240 include multiple layers and/or a graded layer having an increasing percentage of Ge. For example, interface layer 340 in FIG. 3 may comprise a single graded layer of SiGe:B where the Ge percentage increases from section 342 to section 344 to section 346. In another example, interface layers 340 in FIG. 3 may comprise multiple layers of SiGe:B where the Ge percentage increases from layer 342 to layer 344 to layer 346. In yet another example, interface layers 340 in FIG. 3 may comprise a single layer 342 of Si:B or SiGe:B and a graded layer of SiGe:B including sections 344 and 346, where the Ge percentage increases from section 344 to 346. Note that the thicknesses, Ge content, and boron-doping of the layers or graded sections may be selected as desired depending on the end use or target application. For example, the Ge content may be increased from 0% to 30% over a range of 2-10 nm. In such an example, the increase may be stepped in multiple layers such that, for example, layer 342 includes 0% Ge content (Si:B or Si₁₋ₓGeₓ:B where x is 0), layer 344 includes 15% Ge content (Si₁₋ₓGeₓ:B where x is 0.15), and layer 346 includes 30% Ge content (Si₁₋ₓGeₓ:B where x is 0.3). In another example, the increase may be graded over the different sections, such that section 342 includes 0-10% Ge content, section 344 includes 10-20% Ge content, and section 346 includes 20-30% Ge content. In some embodiments, the percentage of Ge content in one interface layer may be determined based on the percentage of Ge content in another interface layer. For example, in the case of FIG. 3, the interface layer 346 nearest the corresponding S/D region 252 or 254 may be 5, 10, 15, 20, or 25% or some other suitable percentage higher than the Ge content in the interface layer 342 nearest the channel region 256. In some embodiments, the Ge content of the interface layer(s) may be based on the Ge content of the SiGe:B S/D regions. For example, the interface layer(s) may include a Ge content grading from a low Ge content (e.g., 0, 5, 10, or 15%) to the Ge content in the SiGe:B S/D regions (e.g., 30, 35, 40, or 50%) or to a percentage of Ge content of 5, 10, 15, or 20%, or some other suitable percentage lower than the percentage of Ge content in the SiGe:B S/D regions.

In some embodiments, deposition 114 may include a substantially conformal growth pattern, such as can be seen in FIGS. 2I and 3. Substantially conformal includes that the thickness of a portion of an interface layer that is between the channel region 256 and the S/D regions 252/254 (e.g., the vertical portion of layer 240 in FIG. 2I, the vertical portion of layers 342, 344, 346 in FIG. 3) is substantially the same (e.g., within 1 or 2 nm tolerance) as the thickness of a portion of the interface layer that is between the S/D regions and the substrate 200 (e.g., the horizontal portion of layer 240 in FIG. 2I, the horizontal portion of layers 342, 344, 346 in FIG. 3). Note that in embodiments including multiple interface layers, the layers may have substantially the same or varying thicknesses. Further note that in embodiments including a graded interface layer, the percentage of Ge content grading may or may not be consistent throughout the layer. Also note that in some instances, multiple interface layers may include some degree of Ge content grading and a graded interface layer may include some degree of stepped Ge content sections that may appear to be different layers. In other words, the transition in the percentage of Ge content throughout interface layer(s) may be gradual, stepped, or some combination thereof. Further note that the transition in the percentage of Ge content from the interface layer(s) to the S/D regions may be gradual, stepped, or some combination thereof. In some embodiments, where the boron-doped interface layers are exposed to heat treatment during one or more annealing processes, the boron may spread out to surrounding layers. Accordingly, the interface region may occupy a wider or narrower region than originally deposited, depending on the thermal history used to complete formation of the semiconductor device(s).

Method 100 of FIG. 1 continues with completing 118 formation of one or more transistors. Completion 118 may include various processes, such as encapsulation with an insulator material, replacement metal gate (RMG) processing, contact formation, and/or back-end processing. For example, contacts may be formed the S/D regions using, for example, a silicidation process (generally, deposition of contact metal and subsequent annealing). Example source drain contact materials include, for example, tungsten, titanium, silver, gold, aluminum, and alloys thereof. In some embodiments, the channel region may be formed to the appropriate transistor configuration, such as forming one or more nanowires/nanoribbons in the channel region for transistors having a nanowire/nanoribbon configuration. Recall that although the structures in FIGS. 2A-I and 3 are shown having a finned non-planar configuration, method 100 of FIG. 1 may be used to form transistors having a planar configuration. The particular channel configurations (e.g., planar, finned, or nanowire/nanoribbon) may be selected based on factors such as the end use or target application or desired performance criteria. Note that the processes 102-118 of method 100 are shown in a particular order in FIG. 1 for ease of description. However, one or more of the processes 102-118 may be performed in a different order or may not be performed at all. For example, box 106 is an optional process that may not be performed if the resulting desired transistor architecture is planar. In another example variation, box 108 may be performed earlier in method 100, depending upon the well doping techniques used. In yet another example variation, a portion of gate processing 110 may be performed later in method 100, such as during a replacement metal gate (RMG) process. Numerous variations on method 100 will be apparent in light of the present disclosure.

FIG. 4A illustrates an example integrated circuit including two transistor structures having finned configurations, in accordance with an embodiment. FIG. 4B illustrates an example integrated circuit including two transistor structures having nanowire configurations, in accordance with an embodiment. FIG. 4C illustrates an example integrated circuit including two transistor structures, one having a finned configuration and one having a nanowire configuration, in accordance with an embodiment. The structures in FIGS. 4A-C are similar to the structure of FIG. 2H, except that only two finned regions are shown to better illustrate the channel regions, for ease of discussion. As can be seen in the example structure of FIG. 4A, the original finned configuration was maintained in the channel regions 402. However, the structure of FIG. 4A may also be achieved by replacing the channel region with a finned structure during a replacement gate process (e.g., an RMG process). In such finned configurations, which are also referred to as tri-gate and fin-FET configurations, there are three effective gates—two on either side and one on top—as is known in the field. As can also be seen in the example structure of FIG. 4A, the interface region 240 is located between the channel region 402 and the S/D region 252. Note that in this example embodiment, the interface region 240 (including one or more interface layers as variously described herein) is also located between the channel region 402 and the S/D region 254; however, the interface region 240 is not shown on the other side of the channel region 402 for ease of illustration.

As can be seen in the example structure of FIG. 4B, the channel region was formed into two nanowires or nanoribbons 404. A nanowire transistor (sometimes referred to as a gate-all-around or nanoribbon transistor) is configured similarly to a fin-based transistor, but instead of a finned channel region where the gate is on three sides (and thus, there are three effective gates), one or more nanowires are used and the gate material generally surrounds each nanowire on all sides. Depending on the particular design, some nanowire transistors have, for example, four effective gates. As can be seen in the example structure of FIG. 4B, the transistors each have two nanowires 404, although other embodiments can have any number of nanowires. The nanowires 404 may have been formed while the channel regions were exposed during a replacement gate process (e.g., an RMG process), after the dummy gate is removed, for example. As can also be seen in the example structure of FIG. 4B, the interface region 240 is located between the channel region 404 and the S/D region 252. Note that in this example embodiment, the interface region 240 (including one or more interface layers as variously described herein) is also located between the channel region 404 and the S/D region 254; however, the interface region 240 is not shown on the other side of the channel region 404 for ease of illustration. Although the structure of FIGS. 4A and 4B illustrate the transistor configurations being the same per each structure, the channel regions may vary. For example, the structure of FIG. 4C illustrates an example integrated circuit including two transistor structures where one has a finned configuration 402 and the other has a nanowire configuration 404. Numerous variations and configurations will be apparent in light of the present disclosure.

FIG. 5A illustrates a band diagram schematic of a conventional p-MOS transistor device. FIG. 5B illustrates a band diagram schematic of a p-MOS transistor device formed in accordance with an embodiment of the present disclosure. Note that both devices include a Si channel region 506 (e.g., an n-type doped Si channel region) and SiGe S/D regions 508 (e.g., boron-doped SiGe S/D regions). The difference between the conventional device in FIG. 5A and the device of FIG. 5B formed using the techniques as variously described herein is that the device of FIG. 5B includes one or more interface layers 517 (between Si channel region 506 and SiGe S/D regions 508) that provide numerous benefits. For example, one benefit can be seen through the example valance bands created by the different devices. The valance band 502 of the conventional device in FIG. 5A shows a valance band offset that arises at the hetero-interface 507 between the Si channel region 506 and the SiGe S/D region 508 due to band-structure differences between the two materials. Such a hetero-interface 507 causes increased resistance during on-state current, thereby decreasing on-state current performance, because positive charged holes (carriers) 509 are required to go over a thermionic emission barrier 504 having high resistance. The p-MOS transistor device of FIG. 5B formed using the techniques variously described herein has a lower thermionic emission barrier 514 as compared to the device of FIG. 5A, as a result of the improved valance band 512 formed by the inclusion of interface layer(s) 517. This improved valance band 512 results in decreased resistance during on-state current, thereby increasing on-state current performance. The resistance reduction and performance improvement is achieved by depositing one or more interface layers 517 as variously described herein.

In an example embodiment where the interface layer(s) 517 comprise a single layer of Si:B, there will be enough p-type dopant across the hetero-interface to allow carriers 509 to tunnel through the interface, rather than relying on traveling over the large hetero-interface 507 thermionic emission barrier 504 of the conventional device of FIG. 5A. In an example embodiment where the interface layer(s) 517 comprise a graded layer of SiGe:B or stepped layers of SiGe:B, the carriers 509 can flow freely or in an improved manner from the SiGe S/D regions 508 to the Si channel region 506. Such performance gains have been measured in the linear regime with a gate bias of 0.6V and a bias of 0.05V on the drain to produce increases of 10-50% in drive current, depending upon the interface layer(s) used. Such performance gains were achieved with interface layer widths of 2-3 nm; however, higher increases may be achievable depending upon the particular configuration used. For example, Conventional p-MOS transistor devices that include epitaxially grown SiGe:B S/D regions may utilize boron out-diffusion from thermal cycles post SiGe:B deposition to provide sufficient doping across the hetero-interface 507 barrier. However, such a process results in a large diffusion tail going into the Si channel region, which causes negative short channel effects, thereby degrading overall device performance. A p-MOS transistor device formed with one or more interface layers using the techniques variously described herein can be formed while keeping thermal cycle post deposition of the SiGe:B S/D regions to a minimum, thereby improving short channel effects (or at least not hurting the short channel effects), while still achieving improved on-state current. Accordingly, the techniques described herein can enable continued transistor performance at very small gate lengths by improving on-current flow bottleneck. Numerous other benefits will be apparent in light of the present disclosure.

Example System

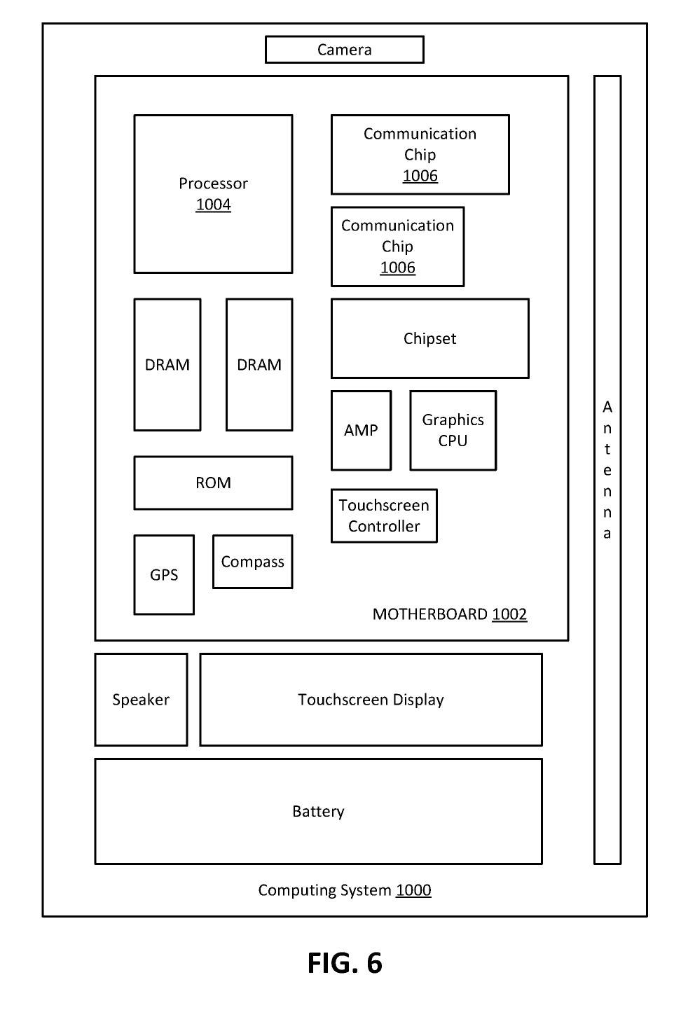

FIG. 6 illustrates a computing system 1000 implemented with integrated circuit structures or devices formed using the techniques disclosed herein, in accordance with various embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or transistor devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or transistor devices formed using the disclosed techniques, as variously described herein.

### Further Example Embodiments

The following examples pertain to further embodiments, from which numerous permutations and configurations will be apparent.

Example 1 is a transistor comprising: a channel region formed from a portion of a silicon (Si) substrate; boron-doped silicon germanium (SiGe:B) source/drain (S/D) regions, wherein the percentage of Ge content in the S/D regions is a first value and greater than 0; and one or more interface layers between the channel region and SiGe:B S/D regions, wherein the one or more interface layers comprise SiGe:B and the percentage of Ge content in the one or more interface layers is a second value less than the first value and greater than or equal to 0.

Example 2 includes the subject matter of Example 1, wherein the one or more interface layers comprise a single layer of boron-doped silicon (Si:B).

Example 3 includes the subject matter of Example 2, wherein the single layer of Si:B has a thickness between the channel region and the corresponding S/D region of 2 to 5 nm.

Example 4 includes the subject matter of Example 1, wherein the one or more interface layers comprise a graded layer of SiGe:B such that the percentage of Ge content in the graded layer increases from a portion nearest the channel region to a portion nearest the corresponding S/D region.

Example 5 includes the subject matter of Example 4, wherein the percentage of Ge content in the graded layer increases from 0 percent Ge to the first value of Ge content.

Example 6 includes the subject matter of Example 4, wherein the percentage of Ge content in the graded layer increases from 0 percent Ge to a percentage at least 10% less than the first value of Ge content.

Example 7 includes the subject matter of Example 4, wherein the percentage of Ge content in the graded layer increases from a percentage greater than 0 to the first value of Ge content.

Example 8 includes the subject matter of Example 4, wherein the percentage of Ge content in the graded layer increases from a percentage greater than 0 to a percentage at least 10% less than the first value of Ge content.

Example 9 includes the subject matter of any of Examples 4-8, wherein the graded layer has a thickness between the channel region and the corresponding S/D region of 2 to 10 nm.

Example 10 includes the subject matter of Example 1, wherein the one or more interface layers comprise a plurality of SiGe:B layers, the percentage of Ge content increasing from a layer nearest the channel region to a layer nearest the corresponding S/D region.

Example 11 includes the subject matter of Example 10, wherein the percentage of Ge content in the layer nearest the channel region is between 0 and 15%.

Example 12 includes the subject matter of any of Examples 10-11, wherein the percentage of Ge content in the layer nearest the corresponding S/D region is at least 10% greater than the percentage of Ge content in the layer nearest the channel region.

Example 13 includes the subject matter of any of Examples 1-12, wherein the one or more interface layers have a substantially conformal growth pattern, such that a thickness of a portion of one or more interface layers between the channel region and the corresponding S/D region is substantially the same as a thickness of a portion of the one or more interface layers between the substrate and the corresponding S/D region.

Example 14 includes the subject matter of Example 13, wherein substantially the same consists of being within 1 nm in thickness.

Example 15 includes the subject matter of any of Examples 1-14, wherein the transistor geometry includes at least one of a field-effect transistor (FET), metal-oxide-semiconductor FET (MOSFET), tunnel-FET (TFET), planar configuration, finned configuration, fin-FET configuration, tri-gate configuration, nanowire configuration, and nanoribbon configuration.

Example 16 is a complementary metal-oxide-semiconductor (CMOS) device including the subject matter of any of Examples 1-15.

Example 17 is a computing system comprising the subject matter of any of Examples 1-16.

Example 18 is a p-type metal-oxide-semiconductor (p-MOS) transistor comprising: an n-type doped silicon (Si) channel region formed from a portion of a Si substrate; boron-doped silicon germanium (SiGe:B) source/drain (S/D) regions, wherein the percentage of Ge content in the S/D regions is a first value and greater than 0; and one or more interface layers between the Si channel region and SiGe S/D regions, wherein the one or more interface layers comprise SiGe:B and the percentage of Ge content in the one or more interface layers is a second value less than the first value and greater than or equal to 0.

Example 19 includes the subject matter of Example 18, wherein the one or more interface layers comprise a single layer of boron-doped silicon (Si:B).

Example 20 includes the subject matter of Example 19, wherein the single layer of Si:B has a thickness between the channel region and the corresponding S/D region of 2 to 5 nm.

Example 21 includes the subject matter of Example 18, wherein the one or more interface layers comprise a graded layer of SiGe:B such that the percentage of Ge content in the graded layer increases from a portion nearest the channel region to a portion nearest the corresponding S/D region.

Example 22 includes the subject matter of Example 21, wherein the percentage of Ge content in the graded layer increases from 0 percent Ge to the first value of Ge content.

Example 23 includes the subject matter of Example 21, wherein the percentage of Ge content in the graded layer increases from 0 percent Ge to a percentage at least 10% less than the first value of Ge content.

Example 24 includes the subject matter of Example 21, wherein the percentage of Ge content in the graded layer increases from a percentage greater than 0 to the first value of Ge content.

Example 25 includes the subject matter of Example 21, wherein the percentage of Ge content in the graded layer increases from a percentage greater than 0 to a percentage at least 10% less than the first value of Ge content.

Example 26 includes the subject matter of any of Examples 21-25, wherein the graded layer has a thickness between the channel region and the corresponding S/D region of 2 to 10 nm.

Example 27 includes the subject matter of Example 18, wherein the one or more interface layers comprise a plurality of SiGe:B layers, the percentage of Ge content increasing from a layer nearest the channel region to a layer nearest the corresponding S/D region.

Example 28 includes the subject matter of Example 27, wherein the percentage of Ge content in the layer nearest the channel region is between 0 and 15%.

Example 29 includes the subject matter of any of Examples 27-28, wherein the percentage of Ge content in the layer nearest the corresponding S/D region is at least 10% greater than the percentage of Ge content in the layer nearest the channel region.

Example 30 includes the subject matter of any of Examples 18-29, wherein the one or more interface layers have a substantially conformal growth pattern, such that a thickness of a portion of one or more interface layers between the channel region and the corresponding S/D region is substantially the same as a thickness of a portion of the one or more interface layers between the substrate and the corresponding S/D region.

Example 31 includes the subject matter of Example 30, wherein substantially the same consists of being within 1 nm in thickness.

Example 32 includes the subject matter of any of Examples 18-31, wherein the transistor geometry includes at least one of a planar configuration, finned configuration, fin-FET configuration, tri-gate configuration, nanowire configuration, and nanoribbon configuration.

Example 33 is a complementary metal-oxide-semiconductor (CMOS) device including the subject matter of any of Examples 18-32.

Example 34 is a computing system comprising the subject matter of any of Examples 18-33.

Example 35 is a method of forming a transistor, the method comprising: forming a fin in a silicon (Si) substrate; forming a gate stack on the Si fin to define a channel region and source/drain (S/D) regions, the channel located underneath the gate stack and the S/D regions on either side of the channel region; etching the S/D regions to form S/D trenches; depositing one or more interface layers in the S/D trenches; and depositing boron-doped silicon germanium (SiGe:B) on the one or more interface layers to form replacement S/D regions, wherein the percentage of Ge content in the replacement S/D regions is a first value and greater than 0; wherein the one or more interface layers comprise SiGe:B and the percentage of Ge content in the one or more interface layers is a second value less than the first value and greater than or equal to 0.

Example 36 includes the subject matter of Example 35, wherein the one or more interface layers comprise a single layer of boron-doped silicon (Si:B).

Example 37 includes the subject matter of Example 35, wherein the one or more interface layers comprise a graded layer of SiGe:B such that the percentage of Ge content in the graded layer increases from a portion nearest the channel region to a portion nearest the corresponding S/D region.

Example 38 includes the subject matter of Example 35, wherein the one or more interface layers comprise a plurality of SiGe:B layers, the percentage of Ge content increasing from a layer nearest the channel region to a layer nearest the corresponding S/D region.

Example 39 includes the subject matter of any of Examples 35-38, further comprising doping the Si channel region with an n-type dopant.

Example 40 includes the subject matter of any of Examples 35-39, wherein depositing the SiGe:B replacement S/D regions includes a chemical vapor deposition (CVD) process.

Example 41 includes the subject matter of any of Examples 35-40, wherein the one or more interface layers have a substantially conformal growth pattern, such that a thickness of a portion of one or more interface layers between the channel region and the corresponding S/D region is substantially the same as a thickness of a portion of the one or more interface layers between the substrate and the corresponding S/D region.

Example 42 includes the subject matter of Example 41, wherein substantially the same consists of being within 1 nm in thickness.

Note that although specific thicknesses are provided in the above examples, the interface layer(s) may occupy a narrower or wider region, depending on the thermal history post deposition of such layer(s). As can be understood based on the present disclosure, the presence of one or more interface layers as variously described herein between a Si channel region (e.g., whether undoped or n-type doped) and replacement S/D regions of a transistor can provide numerous benefits, including, for example, improving short channel effects. Further note that the techniques variously described herein can be used to form transistors of any suitable geometry or configuration, depending on the end use or target application. For example, some such geometries include a field-effect transistor (FET), metal-oxide-semiconductor FET (MOSFET), tunnel-FET (TFET), planar configuration, finned configuration (e.g., tri-gate, fin-FET), and nanowire (or nanoribbon or gate-all-around) configuration, just to name a few example geometries. In addition, the techniques may be used to form CMOS transistors/devices/circuits, where the techniques are used to form the p-MOS transistors within the CMOS, for example.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

1. A transistor comprising:
a body comprising silicon;
a region comprising silicon, germanium, and boron; and
one or more layers between the body and the region, wherein the one or more layers comprise silicon and boron.

2. The transistor of claim 1, wherein the one or more layers consist of a single layer of silicon and boron.

3. The transistor of claim 2, wherein the single layer has a thickness of 2 to 5 nanometers between the body and the region.

4. The transistor of claim 1, wherein the one or more layers comprise a graded layer, the graded layer including germanium, and wherein germanium content in the graded layer increases from a portion nearest the body to a portion nearest the region, the region including an atomic percent of germanium.

5. The transistor of claim 4, wherein the germanium content in the graded layer increases from 0 atomic percent to the atomic percent of germanium included in the region.

6. The transistor of claim 4, wherein the germanium content in the graded layer increases from 0 atomic percent to at least 10 atomic percent less than the atomic percent of germanium included in the region.

7. The transistor of claim 4, wherein the germanium content in the graded layer increases from an atomic percent greater than 0 to the atomic percent of germanium included in the region.

8. The transistor of claim 4, wherein the germanium content in the graded layer increases from an atomic percent greater than 0 to at least 10 atomic percent less than the atomic percent of germanium included in the region.

9. The transistor of claim 4, wherein the graded layer has a thickness of 2 to 10 nanometers between the body and the region.

10. The transistor of claim 1, wherein the one or more layers comprise a plurality of layers, the plurality of layers including silicon, germanium, and boron, germanium content increasing from a layer of the plurality of layers nearest the body to a layer of the plurality of layers nearest the region.

11. The transistor of claim 1, wherein a thickness of a portion of the one or more layers between the body and the region is substantially the same as a thickness of a portion of the one or more layers between an underlying substrate and the region.

12. The transistor of claim 11, wherein substantially the same consists of being within 1 nanometer in thickness.

13. The transistor of claim 1, wherein the transistor includes one or more of a planar configuration, finned configuration, fin-FET configuration, tri-gate configuration, nanowire configuration, nanoribbon configuration, or gate-all-around configuration.

14. A complementary metal-oxide-semiconductor (CMOS) device comprising the transistor of claim 1.

15. A computing system comprising the transistor of claim 1.

16. A transistor comprising:
a body comprising silicon;
a region comprising silicon, germanium, and boron, wherein the region is one of a source region or a drain region, and wherein germanium content is included in the region at a first atomic percent; and
one or more layers between the body and the region, wherein the one or more layers comprise silicon, germanium, and boron, and wherein germanium content is included in at least a portion of the one or more layers at a second atomic percent lower than the first atomic percent.

17. The transistor of claim 16, wherein the second atomic percent is at least 10 atomic percent lower than the first atomic percent.

18. The transistor of claim 16, wherein the one or more layers has a thickness of 1 to 10 nanometers between the body and the region.

19. The transistor of claim 16, wherein boron content is at least 1E20 atoms per cubic centimeter in the one or more layers.

20. The transistor of claim 16, wherein the body is one of a fin, a nanowire, or a nanoribbon.

21. A method of forming a transistor, the method comprising:
providing a body comprising silicon;
forming one or more layers adjacent the body, the one or more layers comprising silicon and boron; and
forming a region adjacent the one or more layers such that the one or more layers are between the body and the region, the region comprising silicon, germanium, and boron.

22. The method of claim 21, wherein the one or more layers consist of a single layer of silicon and boron.

23. The method of claim 21, wherein the one or more layers comprise a graded layer, the graded layer including germanium, and wherein germanium content in the graded layer increases from a portion nearest the body to a portion nearest the region, the region including an atomic percent of germanium.

24. The method of claim 21, wherein the one or more layers comprise a plurality of layers, the plurality of layers including silicon, germanium, and boron, germanium content increasing from a layer of the plurality of layers nearest the body to a layer of the plurality of layers nearest the region.

25. The method of claim 21, wherein the body further comprises at least one of phosphorus or arsenic.
